(19) United States
(12) Patent Application Publication
(10) Pub. No.: US 2005/0023570 A1
(43) Pub. Date: Feb. 3, 2005

(54) Image sensor with transparent transistor gates

(75) Inventors: David N. Nichols, Fairport, NY (US); David L. Losee, Fairport, NY (US)

Correspondence Address: Thomas H. Close;Patent Legal Staff, Eastman Kodak Company, 343 State Street, Rochester, NY, 14650-2201, US

(73) Assignee: Eastman Kodak Company

(21) Appl. No.: 10/629,885

(22) Filed: Jul. 29, 2003

(51) Int. Cl. H01L 27/148

(52) U.S. Cl. 257/222

(57) ABSTRACT

An image sensor includes an image sensing portion for receiving incident light that is converted to a plurality of charge packets; a transfer mechanism for transferring the charge packets from the image sensing portion; and an output structure that receives the charge packets from the transfer mechanism for transporting output signals from the image sensor, wherein the output structure comprises a transparent conductor for a gate electrode gate.

### FIELD OF THE INVENTION

The present invention relates to output circuits for image sensors and, more particularly, to such output circuits having a transparent conductor for a gate electrode gate.

### BACKGROUND OF THE INVENTION

Charge coupled device (CCD) image sensors typically transfer electrons photogenerated in individual picture elements (pixels) to a charge detection circuit which is constructed on the same silicon substrate as the CCD. Prior art devices utilize polycrystalline silicon (polysilicon) gates in arrays of pixels. Prior art devices also include a so-called floating diffusion (FD) node whose voltage changes in response to electrons transferred to it by the shift registers which are part of the CCD. In order to detect the FD voltage changes, and transmit them to other circuits, one or more field effect transistors (FET's) are used to amplify, or buffer, and transmit the FD voltage changes to other circuits. Typically these FET's are also constructed with polysilicon gate electrodes. Polysilicon has been the preferred gate material for the FET gates due to its convenience, being also used as part of the CCD itself, and due to the proven reliability and the low electrical noise characteristics of the transistors with such gates.

Recently, however, CCD's have been developed where all the CCD gates are composed of transparent conducting oxide, such as indium-tin oxide (ITO). The amplifier transistors might, however, still be composed of polysilicon. Although output circuits made with polysilicon gates provide satisfactory electrical performance, they include drawbacks. One such drawback is that their inclusion with a CCD with all ITO gates, necessitates additional manufacturing complexity. It has been found, however, that FET's made with ITO gates also perform satisfactorily in output amplifier circuits. It is therefore an object of the present invention to provide output circuits made with transistor gates of transparent conducting oxide, such as indium tin oxide.

### SUMMARY OF THE INVENTION

The present invention is directed to overcoming one or more of the problems set forth above. Briefly summarized, according to one aspect of the present invention, the invention resides in an image sensor having an image sensing portion for receiving incident light that is converted to a plurality of charge packets; a transfer mechanism for transferring the charge packets from the image sensing portion; and an output structure that receives the charge packets from the transfer mechanism for transporting output signals from the image sensor, wherein the output structure comprises a transparent conductor for a gate electrode gate.

These and other aspects, objects, features and advantages of the present invention will be more clearly understood and appreciated from a review of the following detailed description of the preferred embodiments and appended claims, and by reference to the accompanying drawings.

### BRIEF DESCRIPTION OF THE DRAWINGS

FIG. 1 is a block diagram of the basic elements of an image sensor in accordance with the present invention;

FIG. 2 shows in schematic form the output circuit 18 shown in FIG. 1;

FIG. 3 is a top view showing the layout of portions of the output circuit 18; and

FIG. 4 is a sectional view taken along lines 4-4 of FIG. 3.

### DESCRIPTION OF THE PREFERRED EMBODIMENT

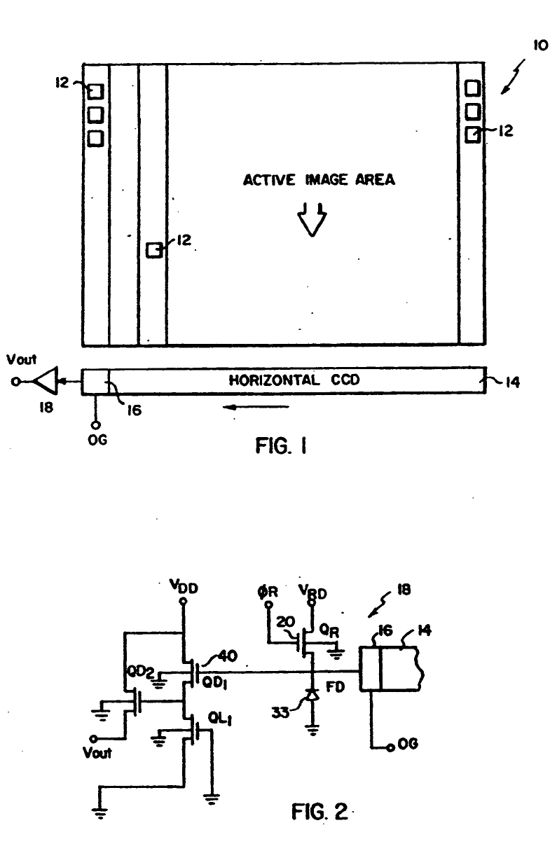

Turning first to FIG. 1, there is shown in block diagrammatic form a full-frame image sensor 10. The image sensor 10 includes photo-elements 12 which collect charge as a linear function of the intensity of incident light and integration time, and as a non-linear function of incident light wavelength. Each photo-element represents one pixel of an image scene. These photo-elements can for example be photo-capacitors which accumulate electrons in an n region of a buried channel. During readout, charge is transferred vertically from photo-capacitor to photo-capacitor in each column to a buried-channel horizontal charge-coupled device (CCD) 14. Each packet of electrons from each photo-element is sequentially delivered to a horizontal CCD element preceding an output gate 16 and then from this element through the output gate to an output circuit 18. The output circuit 18 is integrated on the same chip as the sensor 10. The output circuit 18 provides an output voltage Vₒᵤₜ proportional to each packet of electrons (charge) it receives.

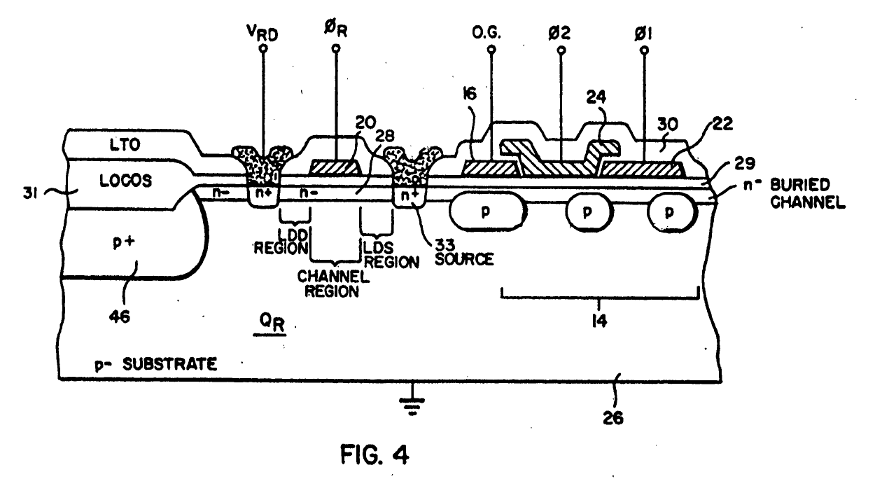

Turning now to FIG. 2, the output circuit 18 is shown in schematic form. In response to the removal of the pulse ΦR applied to the gate electrode 20 of a reset transistor Q_{R}, the transistor Q_{R} is turned off and shortly thereafter, charge is transferred from under the output gate 16 to a floating diffusion FD, 33. As shown in FIG. 4, the floating diffusion is actually the source electrode 33 of the transistor Q_{R}. When the pulse ΦR is applied, the transistor Q_{R} is turned on and the potential across the floating diffusion FD is returned to a reference level set by V_{RD}, the reset drain potential. When transistor Q_{R} is off, a potential well is created in the floating diffusion. Electrons are once again transferred to this potential well from the output gate 16. The floating diffusion 33 is electrically connected to the gate electrode of a transistor QD₁ of the first stage of the source-follower output amplifier 18. In this first stage, there are two transistors QD₁ and QL₁. Both these transistors continuously operate in a saturated mode. At the electrical junction of the transistors QD₁ and QL₁, a voltage is produced which follows the voltage level across the floating diffusion FD. This voltage is applied as an input to the gate electrode of transistor QD₂. The drain of QD₂ is connected to the same potential source V_{DD} which is coupled to the drain of transistor QD₁. All of the transistors, Q_{R}, QD₁, QL₁ and QD₂ are NMOS lightly-diffused drain (LDD) buried-channel transistors. The source and drain electrodes are heavily-doped n⁺, the channel region is under the gate electrode. Lightly-doped (n⁻) source and drain (LDD and LDS) respectively connect the source and drain electrodes to the channel. The gate doesn't overlie the LDD and LDS regions. The output voltage Vₒᵤₜ is taken from the source electrode of transistor QD₂. Vₒᵤₜ is applied as an input to conventional off-chip signal processing circuitry.

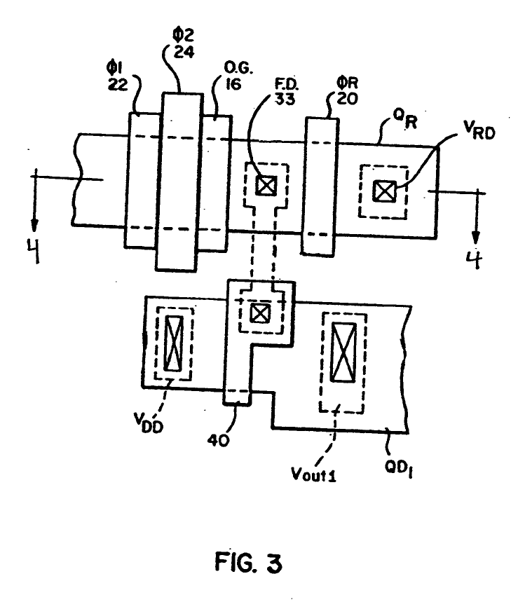

FIG. 3 shows a top layout view of transistor Q_{R} and transistor QD₁ of the first stage of the source-follower output amplifier 18. FIG. 3 should be consulted during the description of FIG. 4. Turning now to FIG. 4 where there is shown in cross-section the reset transistor Q_{R} and the output gate 16 and two gates of the horizontal CCD 14. The CCD 14 is shown as a two-phase device. There are two levels of polysilicon, poly-1 and poly-2 which respectively provide shift register gate electrodes 22 and 24. A substrate 26 is of a p-type conductivity and an n-type layer 28, which can be provided by implanting arsenic into the substrate 26, provides a buried-channel structure. Directly over the n-type layer 28 is a layer of thermally grown silicon dioxide 29. Directly over the p-type substrate 26 is a p⁺ field threshold adjust implant 46 in the non-active regions of the device. Over the p⁺ field threshold adjusted regions 46 is a thick field silicon dioxide layer 31 provided by a conventional LOCOS (Local Oxidation of Silicon) process.

CCD shift register electrodes 22 and 24 are formed on the thin gate oxide 29. Separating each of the electrodes is an insulating layer 30 of silicon dioxide which is provided by a conventional LTO (Low Temperature Oxide). The output gate 16 has a positive potential V_{OG} continuously applied to the electrode. If we assume that electrons are held under the last gate 24 of the horizontal shift CCD 14 and that at this time the gate potential Φ₂ is reduced while the gate potential Φ₁ is raised, the electrons will flow down a “potential hill” under the output gate 16 to the floating diffusion 33. At this time, the transistor Q_{R} is off; that is, signal electrons collect on the source electrode 33. The transistor Q_{R} is an NMOS LDD buried-channel transistor. The source electrode 33 provides the function of a floating diffusion FD. The electrode 33 is a floating diffusion because the potential developed across it is allowed to float when the transistor Q_{R} is off. The floating diffusion is provided at the PN junction between the n⁺ diffused electrode and p (substrate) regions. Then when the pulse ΦR is applied to the gate electrode 20 of transistor Q_{R}, the transistor Q_{R} turns on and the potential across the floating diffusion 33 is reset by the electrons draining off onto the drain of transistor Q_{R} which is at a potential V_{R}D. During these times, a voltage change is produced across the floating diffusion which is electrically connected to the gate electrode 40 of transistor QD₁. It is instructive to note that the gate electrode 40 is composed or made of indium tin oxide. Although only gate electrode 40 is shown as indium tin oxide, similar gate electrodes made also be made of indium tin oxide.

The invention has been described with reference to a preferred embodiment. However, it will be appreciated that variations and modifications can be effected by a person of ordinary skill in the art without departing from the scope of the invention.

### Parts List p0 10 full-frame image sensor

12 photo-element
14 buried-channel horizontal charge-coupled device (CCD)
16 output gate
18 output circuit/source-follower output amplifier
20 gate electrode
22 shift register gate electrode
24 shift register gate electrode
26 substrate
28 n-type layer
29 layer of thermally grown silicon dioxide
30 insulating layer of silicon dioxide
31 thick field silicon dioxide layer (LOCOS)
33 floating diffusion/source electrode
40 gate electrode
46 p⁺ field threshold adjust implant

1. An image sensor comprising:
(a) an image sensing portion for receiving incident light that is converted to a plurality of charge packets;
(b) a transfer mechanism for transferring the charge packets from the image sensing portion; and
(c) an output structure that receives the charge packets from the transfer mechanism for transporting output signals from the image sensor, wherein the output structure comprises a transparent conductor for a gate electrode gate.

2. The image sensor as in claim 1, wherein the transparent conductor is indium tin oxide (ITO).

3. The image sensor as in claim 1, wherein the output structure is a source follower and the transparent conductor is indium tin oxide (ITO).
